(19) United States
(12) Patent Application Publication
(10) Pub. No.: US 2013/0146442 A1
(43) Pub. Date: Jun. 13, 2013

(54) PROFILED SPUTTER TARGET

(71) Applicants: HONG SHENG YANG, PLEASANTON, CA (US); CHI-I LANG, CUPERTINO, CA (US)

(72) Inventors: HONG SHENG YANG, PLEASANTON, CA (US); CHI-I LANG, CUPERTINO, CA (US)

(73) Assignee: INTERMOLECULAR, INC., SAN JOSE, CA (US)

(21) Appl. No.: 13/315,490

(22) Filed: Dec. 9, 2011

(51) Int. Cl. C23C 14/35

(52) U.S. Cl. 204/192.1; 204/298.16

(57) ABSTRACT

In one aspect of the invention, a sputter source is provided. The sputter source includes a target source affixed to a bottom plate of the sputter source. A plurality of magnets spaced apart from each other is included. The plurality of magnets is disposed above a surface of the bottom plate, wherein a surface of the target source is profiled such that the target source has a minimum thickness aligned with an axis of each of the plurality of magnets and a maximum thickness aligned with an axis of a gap defined between each of the plurality of magnets. A method of processing a substrate is also included.

### TECHNICAL FIELD

The present disclosure generally relates to the field of thin film deposition apparatus and methods and more particularly to a sputter target source.

### BACKGROUND

Physical vapor deposition (PVD) is commonly used within the semiconductor industry, as well as within solar, glass coating, and other industries, for depositing thin films over a substrate. Sputter deposition is a physical vapor deposition (PVD) method of depositing thin films by sputtering, that is ejecting material from a source target by high-energy particle bombardment, which then deposits onto a substrate such as a silicon wafer.

The targets composed of ferromagnetic materials are relatively thin, as compared to targets of non-ferromagnetic material, due to the ferromagnetic material's shunting effect of the magnetic field. That is, the magnetic strength at the target surface must be strong enough to ignite and sustain a plasma, and the shunting effect of the magnetic field by the ferromagnetic material restricts the thickness for the target. Due to the high magnetic permeability and the fact that magnetic lines of force decrease drastically relative to target thickness, ferromagnetic targets are thinner than non-ferromagnetic targets in order to permit a sufficient magnetic field to permeate the target surface. Ferromagnetic targets may be 0.25 inches or less, which is substantially thinner than a thickness of non-ferromagnetic targets. Thin targets have an inherently short target life and have to be changed frequently, causing down time for the tools processing the substrates, which in turn impacts throughput and efficiency in a fabrication facility.

What is needed is the ability to have a thicker ferromagnetic target to increase the time between replacement of targets and where the thicker target allows for a sufficient magnetic field to ignite and sustain a plasma.

### SUMMARY

Embodiments of the present invention provide a profiled sputter target that enables sufficient magnetic field penetration. Several inventive embodiments of the present invention are described below.

In one aspect of the invention, a sputter source is provided. The sputter source includes a target source affixed to the front end of the sputter source. A plurality of magnets arranged to form a magnetron with two magnet tracks of opposing polarities, N-(north) and S-(south) tracks, for the igniting and sustaining of a closed-loop plasma is included. The plurality of magnets is disposed behind a bottom surface of the target, wherein the front sputtering surface of the target source is profiled such that the target source has a minimum thickness aligned with the N- and S-track magnets and a maximum thickness aligned with gap defined between the N- and S-track magnets.

In another aspect of the invention a method of processing a substrate is provided. The method includes depositing a layer of material onto the substrate by a sputtering process. While depositing the layer, the method includes applying a magnetic field through a target having a profiled surface, the profiled surface configured so that the target has a minimum thickness aligned with the N- and S-track magnets and a maximum thickness aligned with gap defined between the N- and S-track magnets.

Other aspects of the invention will become apparent from the following detailed description, taken in conjunction with the accompanying drawings, illustrating by way of example the principles of the invention.

### BRIEF DESCRIPTION OF THE DRAWINGS

The present invention will be readily understood by the following detailed description in conjunction with the accompanying drawings. Like reference numerals designate like structural elements.

FIGS. 1A and 1B are simplified schematic cross sectional diagrams illustrating prior art configurations for sputter sources.

FIG. 2 is a simplified schematic diagrams illustrating a target erosion profile and corresponding alignment with the magnetron source disposed behind the target.

FIG. 3 is a simplified schematic diagram illustrating how a profiled target source assembly is optimized in accordance with some embodiments of the invention.

FIG. 4 is a simplified schematic diagram illustrating an alternative configuration for a profiled target source in accordance with some embodiments of the invention.

FIG. 5 is a simplified schematic diagram illustrating an alternative configuration for a profiled target source in accordance with some embodiments of the invention.

### DETAILED DESCRIPTION

The embodiments described herein provide a method and apparatus related to sputter deposition processing. It will be obvious, however, to one skilled in the art, that the present invention may be practiced without some or all of these specific details. In other instances, well known process operations have not been described in detail in order not to unnecessarily obscure the present invention.

The embodiments described herein provide techniques to minimize the downtime of a sputter deposition tool by extending the life of a target source. In some embodiments a profiled target source is provided. The profiled target source has a surface with varying thicknesses across the surface. A first thickness is substantially aligned with N-track magnets, which may be referred to as magnet tracks of a first pole, and S-track magnets which may be referred to as magnet tracks of a second pole, providing a magnetic field permeating the target source. A second thickness is substantially aligned with an axis of a gap defined between the N- and S-track magnets providing the magnetic field. The second thickness is greater than the first thickness. In some embodiments, a smooth transition is provided between the first thickness and the second thickness. With the profiled target, the magnetic field is able to permeate a ferromagnetic target source, such as cobalt, nickel or iron, in order to sustain and ignite a plasma due to the proximity of the magnet to the first thickness of the target source. In some embodiments, the target material has a magnetic permeability of greater than 1.0. In addition, the life of the target source is extended as the portion of the target that erodes quicker is correlated to the second thickness. It should be further appreciated that the embodiments may be applied to any film composition being deposited including but not limited to conductive films, dielectric films, etc.

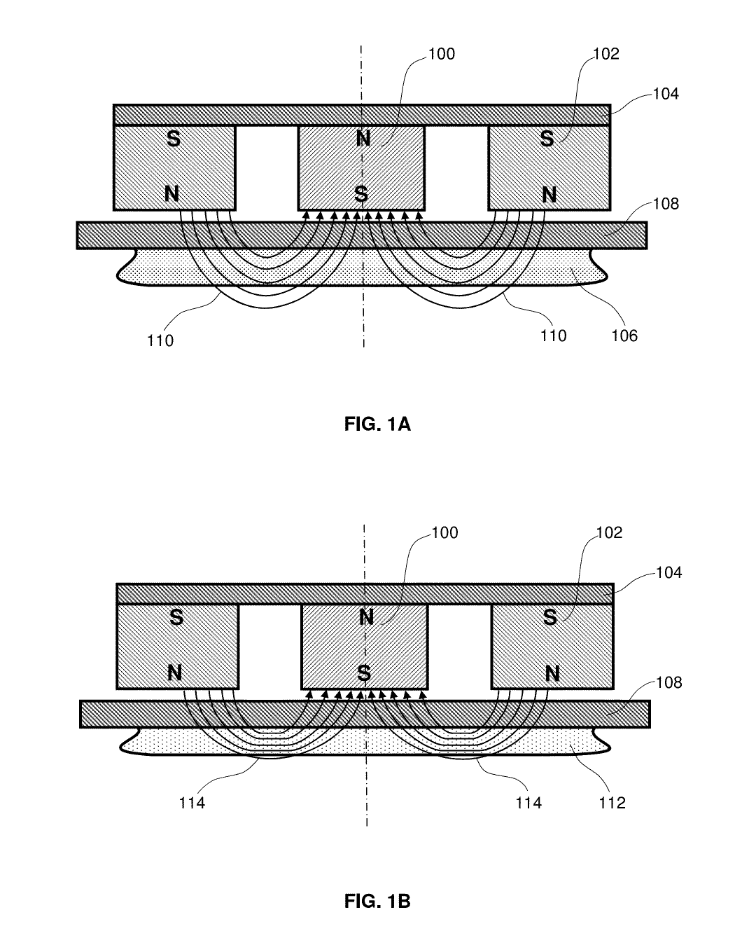

FIGS. 1A and 1B are simplified schematic cross sectional diagrams illustrating prior art configurations for sputter sources. Magnetic shunt plate 104 is affixed to one end of magnets 100 and 102. The other end of S-track magnet 100 and N-track magnet 102 is disposed over target backing plate 108. Non-ferromagnetic target 106 is affixed to an opposing surface of backing plate 108 in FIG. 1A, while ferromagnetic target 112 is affixed to an opposing surface of backing plate 108 in FIG. 1B. It should be appreciated that target backing plate 108 and targets 106 or 112 can be replaced with a so-called monolithic target without a separate backing plate although targets of ferromagnetic materials usually have a separate backing plate to allow greater target thickness. A magnetic field is generated between magnets 100 and 102. In FIG. 1A the magnetic field efficiently permeates through non-ferromagnetic target 106, as illustrated by magnetic field lines 110. However, in FIG. 1B the magnetic field is shunted by ferromagnetic target 112, as illustrated by magnetic field lines 114. Thus, the thickness of 2-10 mm for ferromagnetic target 112 is significantly less than the thickness of 2-50 mm for non-ferromagnetic target 106 in order to ignite and sustain a plasma for a sputtering process. A thin ferromagnetic target is usually bonded to a backing plate to satisfy the mechanical strength requirement for a target.

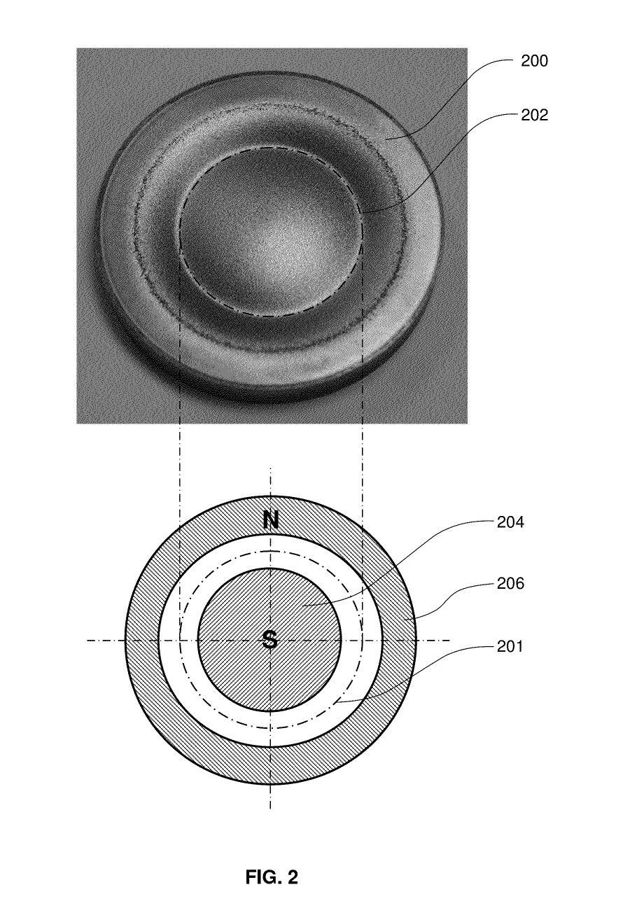

FIG. 2 is a simplified schematic diagrams illustrating a target erosion profile and corresponding alignment with the magnetron sources disposed behind the target. It should be appreciated that top portion of FIG. 2 depicts the surface of the target source 200 with a typical erosion profile for a target with initially uniform thickness, while the bottom portion of FIG. 2 illustrates the configuration and alignment of annular magnets disposed behind the target source. The erosion profile illustrated in the top portion of FIG. 2 depicts an annular erosion groove 202 that experiences a greater amount of erosion than a remainder of the target surface after processing. Erosion groove 202 is substantially aligned with gap 201 defined between center magnet 204 and outer annular magnet 206. Outer peripheral region of the surface of target source 200 has significantly more of the target material remaining, i.e., is thicker, as compared to the amount of material remaining in erosion groove 202. However, due to the depletion of the material in erosion groove 202, the target is no longer useful and changing of the target is necessary, which incurs downtime for the sputter tool.

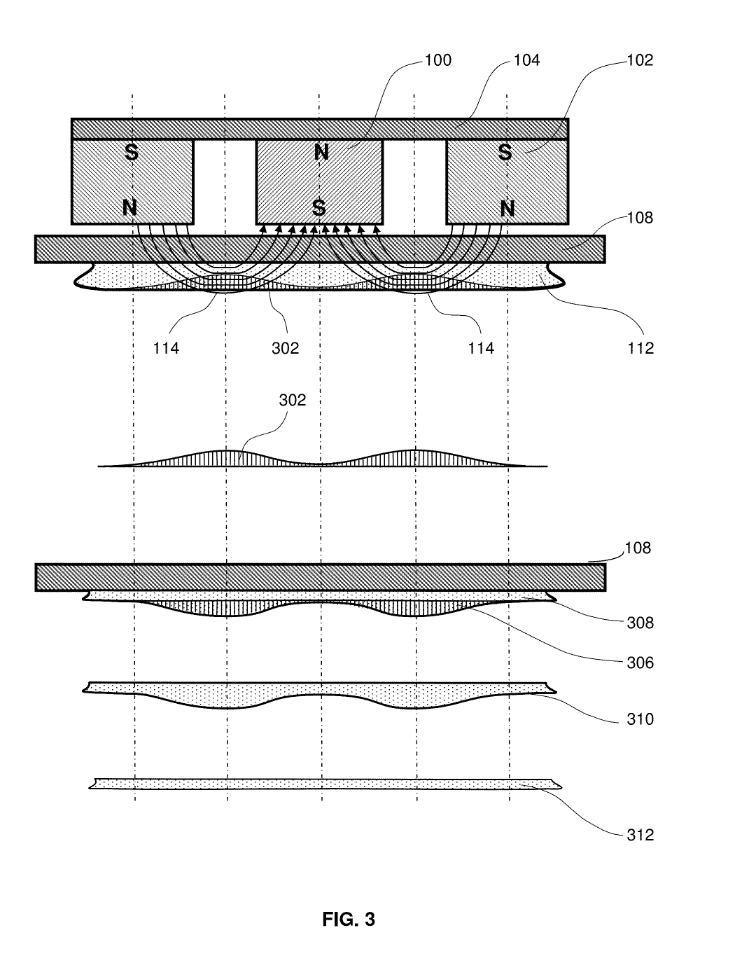

FIG. 3 is a simplified schematic diagram illustrating how a profiled target source assembly is optimized in accordance with some embodiments of the invention. The target source assembly includes a magnet shunt plate 104 having magnets 102 and 100 affixed to a surface of the plate. Magnets 100 and 102 are disposed behind a surface of backing plate 108. In one embodiment magnet 100 may be referred to as a center magnet while magnet 102 may be referred to as an annular outer magnet. Target source 112 is affixed to an opposing surface of backing plate 108. In the top portion of FIG. 3 the erosion profile 300 of a prior art flat target 112 after sputter processing is illustrated by erosion groove or erosion depth 302. Magnetic flux lines 114 emanating from magnets 102 to magnet 100 permeates through ferromagnetic target source 112. Erosion depth 302 and erosion depth profile 304 are illustrated below the target and magnetron assembly of FIG. 3 for explanatory purposes. In some embodiments, the area depicted by erosion groove 302 is inverted in order to define the profiled shape of a target source. That is, the profiled target source is further illustrated as target backing plate 108 with a profiled target source 306 affixed thereto in the lower section of FIG. 3. The profiled target source includes a portion 308 which is a substantially uniformly thick portion, and portion 310 which is a profiled portion of the target material. For example, portion 310 may be defined by the inverted area of erosion groove 302. Portion 308 may be defined by the minimum target material, typical 0.5-2 mm, which is required to be left behind at the end of target life to prevent accidental sputtering of target backing material 108. It should be appreciated that the thickest portion, i.e., the maximum thickness of the surface profile, of the profiled target material is substantially aligned with a gap defined between S-track magnets 100 and N-track magnets 102, while the thinnest portion, i.e., the minimum thickness of the surface profile, is substantially aligned with S-track magnets 100 and N-track magnets 102. A complete illustration of the two portions 308 and 310 of the profiled target material is illustrated as profiled target source 306. As mentioned above, target source 306 is configured with a minimum thickness aligned with the S-track and N-track magnets of the magnetron assembly and a maximum thickness aligned with gaps between the S-track and N-track magnets. It should be further appreciated that target source 306 gradually transitions between the regions of minimum thickness and maximum thickness, i.e., the transition is a smooth transition. Sharper transitions are possible in alternative embodiments. Processing of a substrate with the profiled target source and the magnet configuration illustrated in FIG. 3 results in a longer life for the target source. That is, the maximum thickness regions of profiled target 306 are eroded at a faster rate than the minimum thickness regions, thereby resulting in a substantially flat target profile 312 at the end of target life. End-of-life target profile 312 is desirably comparable to 308, i.e., the minimum target material required to be left behind at the end of target life to prevent accidental sputtering of target backing material 108. Due to the profiled target source, the life of the target is extended in order to minimize the downtime of the tool. It should be appreciated that magnets 100 and 102 may be rotatable around an axis in some embodiments of the invention, or scanned two-dimensionally (X,Y) in other embodiments of the invention.

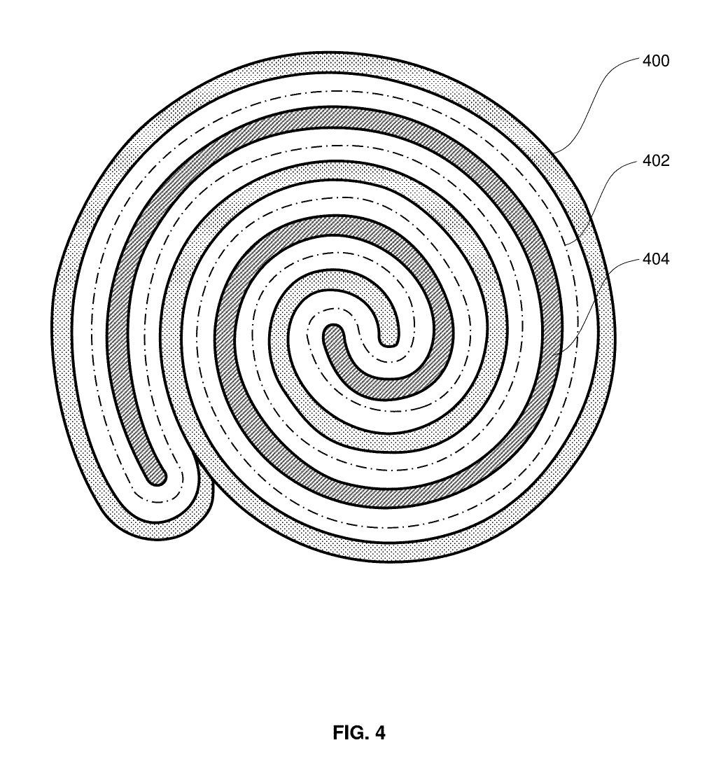

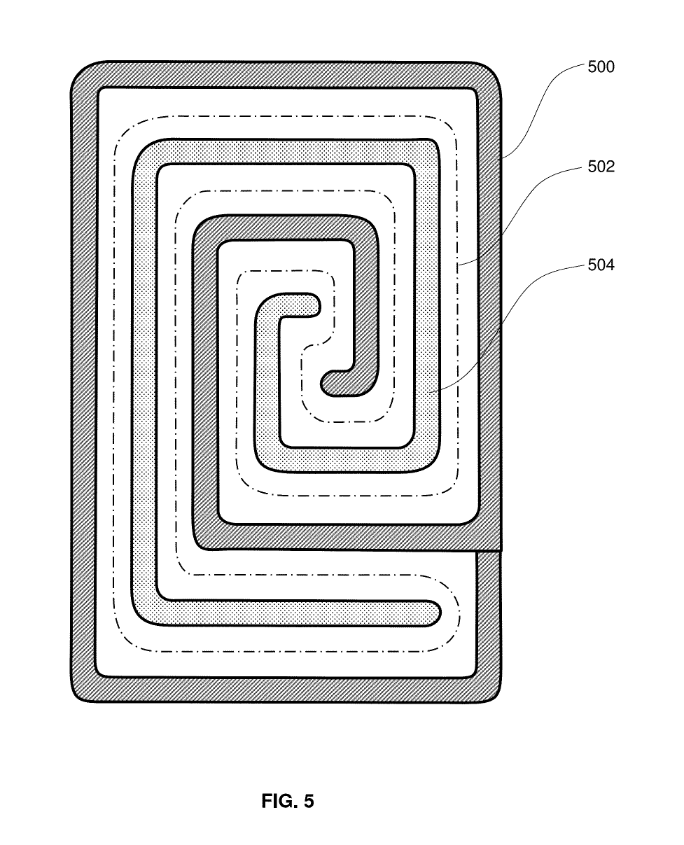

FIG. 4 is a simplified schematic diagram illustrating an alternative configuration for a profiled target source in accordance with some embodiments of the invention. It should be appreciated that while FIG. 3 illustrates a symmetrical design where rotation of the magnets may be incorporated, FIGS. 4 and 5 illustrate designs where rotation is likely not incorporated. Region 400 and region 404 illustrate regions of a profiled target aligned with a corresponding magnet disposed above the profiled target. Region 402 illustrates a gap between the corresponding magnets. Thus, the profiled target of FIG. 4 would have a maximum thickness corresponding to region 402 and a minimum thickness corresponding to region 400 and region 404.

FIG. 5 is a simplified schematic diagram illustrating an alternative configuration for a profiled target source in accordance with some embodiments of the invention. Region 500 and region 504 illustrate regions of a profiled target aligned with a corresponding magnet disposed above the profiled target. Region 502 illustrates a gap between the corresponding magnets. The profiled target of FIG. 5 has a maximum thickness corresponding to region 502 and a minimum thickness corresponding to region 500 and region 504. In some embodiments, the transition between the maximum and minimum thicknesses of FIGS. 4 and 5 is a transition as illustrated with reference to FIG. 3. The profiles of FIGS. 3-5 are illustrated for exemplary purposes and not meant to be limiting as any suitable profile where the thickness of the target is correlated to the magnet placement as described above may be integrated with a sputter source as described herein.

Although the foregoing invention has been described in some detail for purposes of clarity of understanding, it will be apparent that certain changes and modifications can be practiced within the scope of the appended claims. Accordingly, the present embodiments are to be considered as illustrative and not restrictive, and the invention is not to be limited to the details given herein, but may be modified within the scope and equivalents of the appended claims. In the claims, elements and/or steps do not imply any particular order of operation, unless explicitly stated in the claims.

What is claimed is:

1. A sputter source, comprising:
a target affixed to a bottom plate of the sputter source, wherein the target has first sets of regions having a first thickness and second sets of regions having a second thickness, and wherein the thickness of the second sets of regions is greater than the thickness of the first sets of regions;
a first plurality of magnets arranged in a first assembly wherein the poles of each of the magnets of the first assembly are aligned in a same direction and are aligned perpendicular to the bottom plate;
a second plurality of magnets arranged in a second assembly wherein the poles of each of the magnets of the second assembly are aligned in a same direction and are aligned perpendicular to the bottom plate, and wherein the poles of the plurality of magnets arranged in the second assembly are opposite in polarity of the magnets of the first assembly; and
wherein the first sets of regions of the target are aligned with one of the first assembly of magnets or aligned with the second assembly of magnets, and wherein the second sets of regions of the target are not aligned with either the first assembly of magnets or the second assembly of magnets.

2. The sputter source of claim 1, wherein the target is composed of a ferromagnetic material.

3. The sputter source of claim 1, wherein the target has a magnetic permeability of greater than 1.0.

4. The sputter source of claim 2 wherein the ferromagnetic material includes one of iron, nickel or cobalt.

5. The sputter source of claim 1, wherein the first plurality of magnets and the second plurality of magnets include a center magnet and an annular outer magnet.

6. The sputter source of claim 1, wherein the first plurality of magnets and the second plurality of magnets are rotatable.

7. The sputter source of claim 1, wherein the sputter source has a diameter that is less than a diameter of a substrate being processed.

8. A method of processing a substrate, comprising;
depositing a layer of material onto the substrate through a sputtering process; and
while depositing the layer, applying a magnetic field through a target having a profiled surface,
the magnetic field emanating from a first plurality of magnets and a second plurality of magnets;
the first plurality of magnets arranged in a first assembly wherein the poles of each of the magnets of the first assembly are aligned in a same direction and are aligned perpendicular to the bottom plate;
the second plurality of magnets arranged in a second assembly wherein the poles of each of the magnets of the second assembly are aligned in a same direction and are aligned perpendicular to the bottom plate, and wherein the poles of the plurality of magnets arranged in the second assembly are opposite of the poles of the magnets of the first assembly;
the profiled surface configured so that first sets of regions of the target are aligned with one of the first assembly of magnets or aligned with the second assembly of magnets, and wherein second sets of regions of the target are not aligned with either the first assembly of magnets or the second assembly of magnets.

9. The method of claim 8, wherein the target is composed of a ferromagnetic material.

10. The method of claim 8, further comprising:
rotating the plurality of magnets.

11. The method of claim 8 wherein the depositing includes processing different regions of the substrate in a combinatorial manner.

12. The method of claim 8, wherein the combinatorial processing includes changing a process condition for at least two of the different regions of the substrate.
